(19) United States
(12) Patent Application Publication
(10) Pub. No.: US 2025/0353734 A1
(43) Pub. Date: Nov. 20, 2025

(54) SEMICONDUCTOR DEVICE WITH A MICROMECHANICAL COMPONENT

(71) Applicant: Robert Bosch GmbH, Stuttgart (DE)

(72) Inventors: Jochen Reinmuth, Reutlingen (DE); Amin Jemili, Kusterdingen (DE); Frieder Haag, Wannweil (DE)

(21) Appl. No.: 18/854,861

(22) PCT Filed: May 8, 2023
(86) PCT No.: PCT/EP2023/062143

§ 371 Date: Oct. 7, 2024

(30) Foreign Application Priority Data
May 30, 2022 (DE) 10 2022 205 388.5

(51) Int. Cl. B81B 7/00; B81C 1/00

(52) U.S. Cl. CPC B81B 7/0058; B81C 1/00333; B81B 2201/0257; B81B 2201/0264; B81B 2203/0315; B81C 2203/0154

(57) ABSTRACT

A semiconductor device. The semiconductor device includes a micromechanical component, an injection-molded body with at least one recess formed on the injection-molded body, which is framed by a lateral wall region of the injection-molded body and is at least partially covered by a base region of the injection-molded body on a first side of the recess, and a lid which is fastened directly or via at least one intermediate component to the lateral wall region and covers the recess on its second side. A through-opening is formed on the base region of the injection-molded body. The at least one lateral wall of which extends from the recess to an outer base surface of the base region faces away from the recess. The micromechanical component is arranged in the through-opening such that the micromechanical component mechanically contacts the at least one lateral wall of the through-opening.

### FIELD

The present invention relates to a semiconductor device with a micromechanical component. The present invention also relates to a production method for a semiconductor device.

### BACKGROUND INFORMATION

FIG. 1 shows a schematic illustration of a conventional pressure sensor, which is applicant's internal prior art.

The conventional pressure sensor schematically illustrated in FIG. 1 has a micromechanical component 10 which is arranged in an interior space 12 of a housing formed by a base plate 14, a side part 16 fastened to the base plate 14 and a lid 18 fastened to the side part 16. The lid 18 has a supply opening 20, which is why a pressure p present in the interior space 12 corresponds to an ambient pressure of the conventional pressure sensor, while a reference pressure p₀ is confined in an internal volume 22 of the micromechanical component 10.

The micromechanical component 10 is formed with a deformable membrane 24, on the first membrane surface 24a of which the pressure p in the interior space 12 acts, while a second membrane surface 24b of the deformable membrane 24 facing away from the first membrane surface 24a borders the internal volume 22 with the reference pressure p₀ present therein. A pressure difference between the pressure p in the interior space 12 and the reference pressure p₀ should be measurable by means of a voltage or capacitance applied between the deformable membrane 24 and an associated counter electrode 26.

An application-specific circuit 28 is also arranged in the interior space 12, which is electrically connected to the micromechanical component 10 via a first bonding wire connection 30 and to the housing of the conventional pressure sensor via a second bonding wire connection 32. The micromechanical component and the application-specific circuit 28 can, for example, each be bonded to the base plate 14 via an adhesive bond 34. In addition, the conventional pressure sensor also has solder balls 36 on an underside of the base plate 14 facing away from the interior space 12.

### SUMMARY

The present invention provides a semiconductor device and a production method for a semiconductor device.

The present invention provides semiconductor devices that can be manufactured cost-effectively by performing a highly parallelized manufacturing process using standard semiconductor technologies. As the following description also makes clear, a semiconductor device according to the present invention has a comparatively robust structure in which, in particular, the risk of acoustic leakage paths forming is reliably avoided. The present invention thus contributes to increasing the yield of the manufacturing process for a plurality of semiconductor devices.

In an advantageous embodiment of the semiconductor device of the present invention, the micromechanical component comprises at least one structured or unstructured substrate comprising at least one semiconductor material, wherein the micromechanical component is arranged in the through-opening such that at least one outer surface of the at least one substrate of the micromechanical component mechanically contacts the at least one lateral wall of the through-opening. The at least one outer surface of the substrate of the micromechanical component can thus be used as a contact surface of the injection-molded body in a cost-effective manner. This is advantageous because the molding compound forming the injection-molded body can be brought into firm mechanical contact with the at least one outer surface of the at least one substrate, in particular into airtight and gas-tight mechanical contact with the at least one outer surface of the at least one substrate, in a simple manner by means of overmolding the micromechanical component. The mechanical contact of the at least one lateral wall of the through-opening formed in this way with the at least one outer surface of the substrate also generally has a relatively long stability/lifetime.

Preferably, according to an example embodiment of the present invention, the recess is covered on its first side by the base region of the injection-molded body and by the micromechanical component arranged in the through-opening. This means that the risk of an acoustic leakage path occurring on the first side of the recess is also prevented by means of the airtight and gas-tight design of the mechanical contact of the at least one lateral wall of the through-opening with the micromechanical component.

Preferably, according to an example embodiment of the present invention, the lid is fastened in an airtight and gas-tight manner to the lateral wall region directly or via the at least one intermediate component, and the mechanical contact of the at least one lateral wall of the through-opening with the micromechanical component is airtight and gas-tight, whereby the recess is sealed off from an outer volume of the semiconductor device in an airtight and gas-tight manner by means of the injection-molded body, the lid, and the micromechanical component. In this case, a total volume of the recess can be used as a reference volume for providing a reference pressure, wherein pressure detections and sound detections with a relatively high sensitivity are possible using the micromechanical component of the embodiment described herein due to the comparatively large total volume of the recess.

For example, the micromechanical component arranged in the through-opening has at least one deformable membrane, on the respective first membrane surface of which a pressure prevailing in the outer volume acts and on the respective second membrane surface of which, facing away from the first membrane surface, a reference pressure enclosed in the recess acts. Due to the comparatively large total volume of the recess, (nearly) no counter-pressure builds up to counteract the deformation, even if the membrane is strongly deformed, which is why pressure detection and sound detection with a relatively high sensitivity is possible using the embodiment of the semiconductor device described here.

As an advantageous further development of the present invention, the micromechanical component arranged in the through-opening may have a spacer at its end aligned with the recess, wherein at least one spacer side surface of the spacer mechanically contacts the at least one lateral wall of the through-opening. This allows positioning of at least one sensitive component of the micromechanical component at a distance from an edge of the through-opening in the base region of the injection-molded body bordering the recess, thereby significantly reducing the risk of undesired contact of the positioning of the at least one sensitive component of the micromechanical component with the molding compound of the injection-molded body to be formed. The micromechanical component of the embodiment described here can therefore also comprise at least one very sensitive membrane without the risk of damaging it during the manufacture of the respective semiconductor device.

Alternatively or additionally, according to an example embodiment of the present invention, the micromechanical component arranged in the through-opening may have an application-specific circuit device, wherein at least one lateral surface of the application-specific circuit device mechanically contacts the at least one lateral wall of the through-opening. The design described here makes it easier to integrate the application-specific circuit device into the micromechanical component.

The semiconductor device can be, for example, a pressure sensor, a sound sensor or a microphone. However, it should be noted that the embodiments of the semiconductor device listed here are not to be interpreted exhaustively.

Performing a corresponding production method for a semiconductor device also provides the advantages explained above. It is pointed out that the production method can be developed further according to the embodiments of the semiconductor device explained above.

According to an example embodiment of the present invention, preferably, the micromechanical component is overmolded with a molding compound of the subsequent injection-molded body using a punch to form the injection-molded body. The punch can be used to ensure that the desired shape of the subsequent injection-molded body is maintained.

In particular, a film can be arranged between the punch and the micromechanical component before the micromechanical component is overmolded with the molding compound of the subsequent injection-molded body, which film is removed after the micromechanical component has been overmolded with the molding compound and the punch has been removed from the overmolded micromechanical component. By using the film, an advantageous tolerance compensation can be achieved.

### BRIEF DESCRIPTION OF THE DRAWINGS

Further features and advantages of the present invention are explained below with reference to the figures.

FIG. 1 shows a schematic illustration of a conventional pressure sensor.

FIG. 2 shows a schematic illustration of a first example embodiment of the semiconductor device according to the present invention.

FIG. 3 shows a schematic illustration of a second example embodiment of the semiconductor device of the present invention.

FIG. 4 shows a schematic illustration of a third example embodiment of the semiconductor device of the present invention.

FIGS. 5A to 5F show schematic illustrations of intermediate products to explain an example embodiment of a production method for a semiconductor device, according to the present invention.

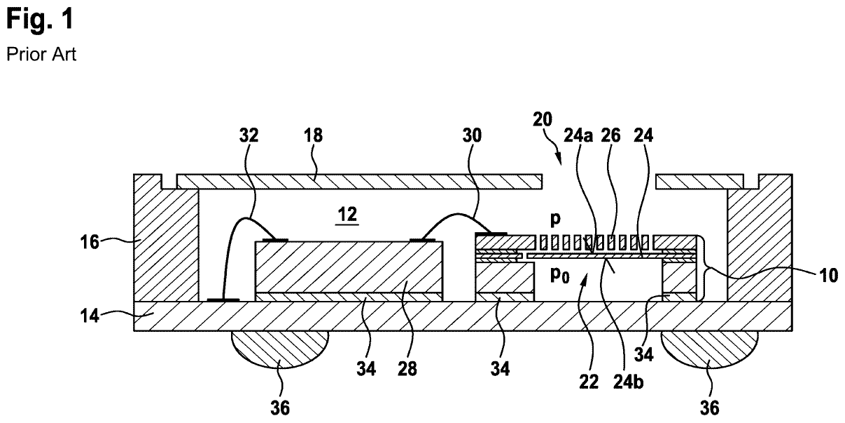

### DETAILED DESCRIPTION OF EXAMPLE EMBODIMENTS

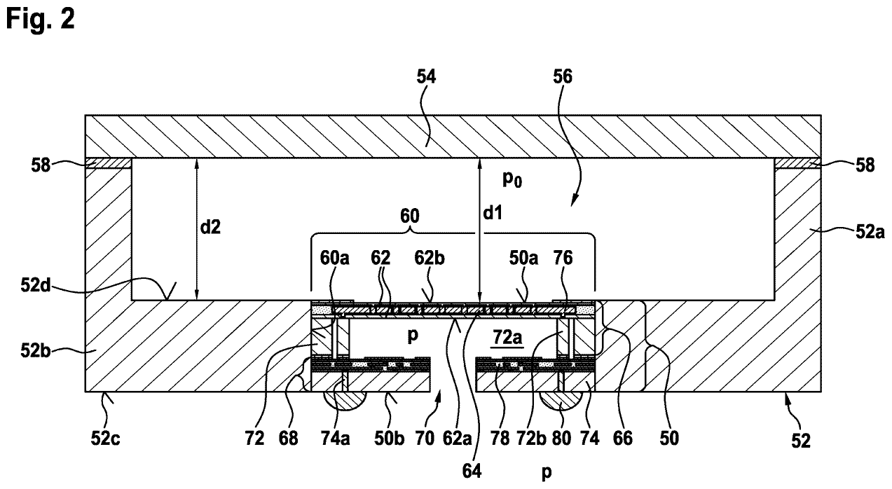

FIG. 2 shows a schematic illustration of a first embodiment of the semiconductor device.

The semiconductor device illustrated schematically in FIG. 2 comprises a micromechanical component 50, an injection-molded body 52 and a lid 54. At least one recess 56 is formed on the injection-molded body 52, which is framed by a so-called lateral wall region 52a of the injection-molded body 52 and is at least partially covered on a first side of the recess 56 by a so-called base region 52b of the injection-molded body 52. It should be noted that the injection-molded body 52 is preferably to be understood as a compact body made of a molding compound, on which the lateral wall region 52a and the base region 52b are formed integrally with one another. The injection-molded body 52 can be formed from the molding compound in a single injection molding step. The recess 56 formed on the injection-molded body 52 extends at least from its first side to at least a second side of the recess 56 faced away from the first side. The lid 54 is fastened to the lateral wall region 52a on the second side of the recess 56, either directly or via at least one intermediate component 58. The first side of the recess 56 is thus to be understood as a side/“base region side” of the recess 56 facing away from the lid 54, while the second side of the recess 56 can be described as a “lid side.”

The lid 54 covers the recess 56 (preferably completely) on its second side. The lid 54 may also be referred to as a cap 54 or a capping 54 of the semiconductor device. The at least one intermediate component 58 may be, for example, an adhesive bond or a mold joint 58. By way of example only, in the embodiment of FIG. 2, the lid 54 is fastened to the lateral wall region 52a of the injection-molded body 52 via a so-called sheet-mold joint 58.

As can be seen in FIG. 2, a through-opening 60 is formed at the base region 52b of the injection-molded body 52. The through-opening 60 is framed by the base region 52b of the injection-molded body 52. At least one lateral wall 60a of the through-opening 60 extends from the recess 56 to an outer base surface 52c of the base region 52b, which is facing away from the recess 56. The micromechanical component 50 is arranged in the through-opening 60 such that the micromechanical component 50 mechanically contacts the at least one lateral wall 60a of the through-opening 60.

In the semiconductor device described here, the micromechanical component 50 is thus at least partially integrated into the base region 52b of the injection-molded body 52. The arrangement of the micromechanical component 50 on the semiconductor device can thus be carried out in a common process step with the formation of the injection-molded body 52. An additional process step for placing the micromechanical component 50 on/in the injection-molded body 52 after forming the injection-molded body 52, such as the conventional bonding of the micromechanical component 50 on/in the injection-molded body 52, is thus not necessary for manufacturing the semiconductor device described here. The semiconductor device of FIG. 2 can therefore be produced comparatively cost-effectively.

For the base region 52b of the injection-molded body 52, an inner base surface 52d facing away from its outer base surface 52c can be definable, which borders the recess 56 at a maximum distance from the lid 54. Similarly, a component surface 50a can be definable for the micromechanical component 50, which is aligned with the recess 56 and has the smallest distance from the lid 54 of all surfaces of the micromechanical component 50. Preferably, a first distance d1 of the component surface 50a of the micromechanical component 50 from the lid 54 is greater than or equal to a second distance d2 of the inner base surface 52d of the base region 52b from the lid 54. In this case, the micromechanical component 50 is completely integrated/recessed in the base region 52b of the injection-molded body 52. The recess 56 formed in the injection-molded body 52 is thus not required as a receiving volume of the micromechanical component 50, so that a total volume of the recess 56 can therefore be advantageously used for other purposes.

The recess 56 can be (completely) covered on its first side (facing away from the lid 54) by the base region 52b of the injection-molded body 52 and by the micromechanical component 50 arranged in the through-opening 60. This is advantageous because the mechanical contact of the at least one lateral wall 60a of the through-opening 60 with the micromechanical component 50 can be formed in airtight and gas-tight fashion in a simple manner during the injection molding of the injection-molded body 52. The lid 54 can also be easily fastened to the lateral wall region 52a of the injection-molded body 52 in an airtight and gas-tight manner, either directly or via the at least one intermediate component 58. The recess 56 can therefore be sealed airtight and gas-tight from an outer volume of the semiconductor device by means of the injection-molded body 52, the lid 54 and the micromechanical component 50 with a comparatively small amount of work.

Preferably, the recess 56 is sealed airtight and gas-tight with respect to the outer volume of the semiconductor device by means of the injection-molded body 52, the lid 54 and the micromechanical component 50. In this case, the injection-molded body 52, the lid 54 and the micromechanical component 50 form an airtight and gas-tight housing of the recess 56, which has a robust structure and in which the risk of acoustic leakage paths forming is comparatively low. The semiconductor device equipped with the micromechanical component 50 and the airtight and gas-tight recess 56 can therefore be used in a variety of ways.

By way of example only, the semiconductor device of FIG. 2 is designed as a pressure sensor/capacitive pressure sensor, as a sound sensor, such as in particular as a structure-borne sound sensor, or as a microphone. For this purpose, the micromechanical component 50 arranged in the through-opening 60 comprises at least one deformable membrane 62, which can be electrically contacted together with at least one counter-electrode 64 of the micromechanical component 50 such that a voltage or capacitance applied between the at least one deformable membrane 62 and the at least one counter-electrode 64 can be tapped/ascertained. A respective first membrane surface 62a of the at least one deformable membrane 62 is faced away from the recess 56 such that a pressure p prevailing in the outer volume of the semiconductor device acts on the first membrane surface 62a. In contrast, a second membrane surface 62b facing away from the first membrane surface 62a is aligned with the recess 56 such that a reference pressure p₀ enclosed in the recess 56 acts on the second membrane surface 62b. The recess 56 can thus be used as a reference volume for the reference pressure p₀ in the semiconductor device of FIG. 2, wherein, due to the comparatively large total volume of the recess 56, hardly any pressure build-up occurs in the recess 56 even if the at least one deformable membrane 62 is strongly deformed into the recess 56. Thus, the indentation of the at least one membrane 62 into the recess 56 also does not lead to a counter-pressure in the recess 56 that counteracts the indentation. As can be seen in FIG. 2, the total volume of the recess 56 can be at least a factor of 2 larger than the total volume of the micromechanical component 50. Such a large reference volume for the reference pressure p₀ helps to increase the sensitivity of the semiconductor device used as a pressure sensor, sound sensor or microphone.

However, it should be noted that the at least one deformable membrane 62 and the at least one counter-electrode 64 are only examples of possible components of a micromechanical device 66 of the micromechanical component 50. As an alternative or as a supplement to the components 64 and 66, the micromechanical device 66 of the micromechanical component 50 may also comprise at least one seismic mass, at least one actuator electrode and/or at least one stator electrode. At least one lateral wall of the micromechanical device 66 may have a mechanical contact with the at least one lateral wall 60a of the through-opening 60. However, it may also be possible to dispense with the formation of the micromechanical device 66 on the micromechanical component 50.

Advantageously, the micromechanical component 50 of the semiconductor device of FIG. 2 arranged in the through-opening 60 also has an application-specific circuit device 68. In this case, at least one lateral surface of the application-specific circuit device 68 can mechanically contact the at least one lateral wall 60a of the through-opening 60. This also eliminates the conventional need to place an application-specific circuit formed separately from the micromechanical component 50 on/in the injection-molded body 52 after forming the injection-molded body 52 and to form an electrical connection of the micromechanical component 50 to the application-specific circuit formed separately therefrom via at least one bonding wire connection. This further reduces the amount of work required to manufacture the semiconductor device. Furthermore, in this case the total volume of the recess is not impaired by the application-specific circuit device 68.

As shown in FIG. 2, the application-specific circuit device 68 can also be located on a side of the micromechanical device 66, in particular of the at least one deformable membrane 62, of the micromechanical component 50 arranged in the through-opening 60, which is facing away from the recess 56/the lid 54. By means of at least one access opening 70 extending in each case through the application-specific circuit device 68, the pressure p prevailing in the outer volume of the semiconductor device can nevertheless be conducted to the micromechanical device 66 of the micromechanical component 50.

The micromechanical component 50 may have at least one structured or unstructured substrate 72 and 74, each comprising at least one semiconductor material, such as silicon in particular. Preferably, the micromechanical component 50 is arranged in the through-opening 60 such that at least one outer surface of the at least one substrate 72 and 74 of the micromechanical component 50 mechanically contacts the at least one lateral wall 60a of the through-opening 60. This is advantageous because the molding compound injected onto the at least one outer surface of the at least one substrate 72 and 74 generally forms an airtight and gas-tight mechanical contact with the at least one outer surface contacted thereby.

By way of example only, the micromechanical component 50 of the semiconductor device of FIG. 2 arranged in the through-opening 60 has, on a side of its micromechanical device 66 aligned with the recess 56 and the lid 54, a functional layer structure 76 arranged on a first substrate 72, in which, for example, the at least one deformable membrane 62 and the at least one counter electrode 64 are formed. At least one cavity 72a at least partially exposing the functional layer structure 76 and/or at least one through-contact 72b may be formed on the first substrate 72. A circuit layer structure 78 formed on a second substrate 74 is disposed on a side of the application-specific circuit device 68 of the semiconductor device of FIG. 2 that is aligned with the recess 56 and the lid 54. At least one through-contact 74a can also run through the second substrate 74. The micromechanical device 66 and the application-specific circuit device 68 may be fastened to each other via at least one bond connection. Optionally, at least one solder ball 80 may also be provided on an outer component surface 50b of the micromechanical component 50 facing away from the recess 56 and the lid 54.

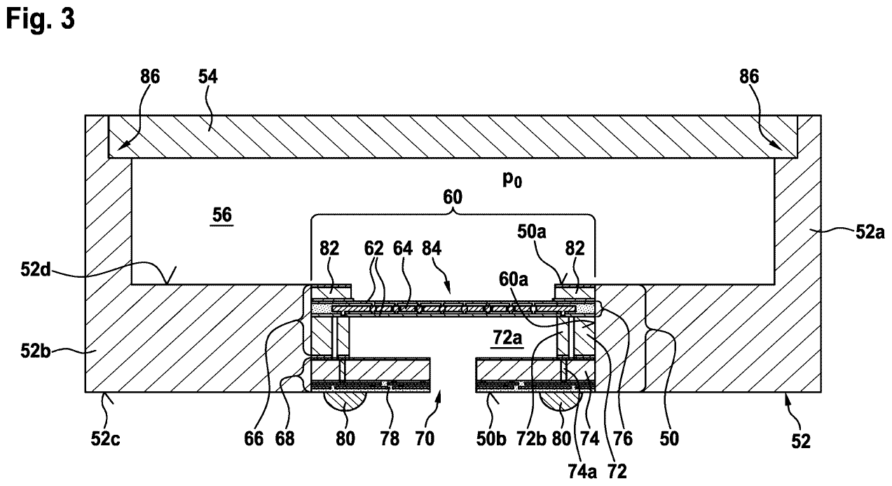

FIG. 3 shows a schematic illustration of a second embodiment of the semiconductor device.

In the semiconductor device shown schematically in FIG. 3, the micromechanical component 50 arranged in the through-opening 60 also comprises a spacer 82, which is located at an end of the micromechanical component 50 aligned with the recess 56 and with the lid 54, as an advantageous further development compared with the embodiment described above. Also, at least one spacer side surface of the spacer 80 may be mechanically contacted by the at least one lateral wall 60a of the through-opening 60. Possibly, at least one access opening 84 may be formed on the spacer 82, by means of which, for example, the micromechanical device 66 of the micromechanical component 50 is at least partially kept clear/exposed by the spacer 82. The spacer 82 can, for example, be designed as an annular spacer 82. In particular, the spacer 82 may be formed from a material deposited on the functional layer structure 76.

The spacer 82 makes possible the placement of the micromechanical device 66 of the micromechanical component 50 within the opening 60 in a recessed position compared to the inner base surface 52d. As will become clear from the production method described below, it is possible in this way to prevent the micromechanical device 66 of the micromechanical component 50, in particular the at least one deformable membrane 62, from coming into contact with a punch used for this purpose during the molding process/injection molding of the injection-molded body 52. The semiconductor device described herein can therefore still be manufactured relatively cost-effectively and simply even if its micromechanical component 50 is equipped with at least one comparatively sensitive deformable membrane 62.

As a further optional development, a groove 86, into which the lid 54 is clamped, is also formed at an end of the lateral wall region 52a of the injection-molded body 52 of the semiconductor device of FIG. 3 facing away from the base region 52b. An amount of adhesive required to fasten the lid 54 to the injection-molded body 52 can be reduced by means of the formation of the groove 86. In particular, the groove 86 can also make possible a fastening of the lid 54 to the injection-molded body 52 without the use of an adhesive. The formation of the groove 86 on the lateral wall region 52a of the injection-molded body 52 also increases the stability and robustness of the realized semiconductor device.

With respect to further properties and features of the semiconductor device of FIG. 3 and its advantages, reference is made to the above-explained embodiment of FIG. 2.

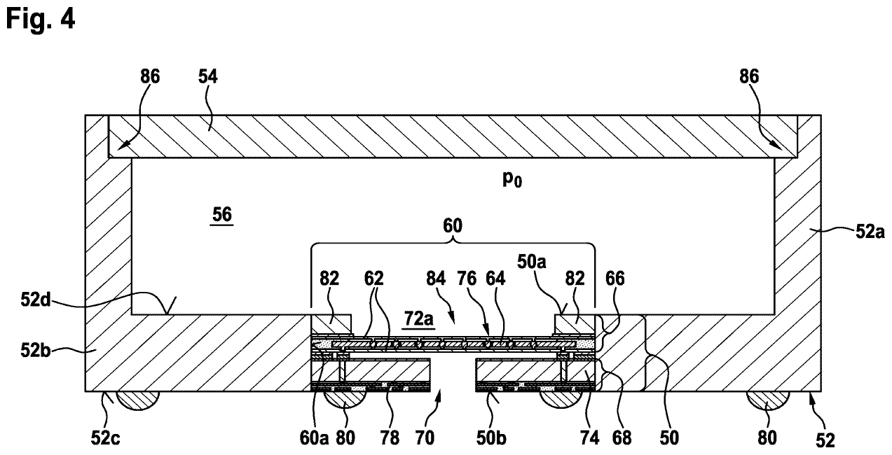

FIG. 4 shows a schematic illustration of a third embodiment of the semiconductor device.

As can be seen from FIG. 4, the spacer 82 can also be structured out of the at least one substrate 72 and 74 of the micromechanical component 50, in particular out of the first substrate 72 of the micromechanical device 66. Where appropriate, the micromechanical device 66 and the application-specific circuit device 68 may also be fastened to each other via at least one bond connection formed between the functional layer structure 76 and the second substrate 74 of the application-specific circuit device 68.

If desired, at least one solder ball 80 may also be attached to the outer base surface 52c of the base region 52b facing away from the recess 56.

With respect to further properties and features of the semiconductor device of FIG. 4 and its advantages, reference is made to the embodiments of FIGS. 2 and 3.

All the semiconductor devices described above can be operated with very low power consumption due to their high sensitivity. By way of example only, the micromechanical components 50 of the semiconductor devices described above are designed as a pressure sensor/capacitive pressure sensor, as a sound sensor, in particular as a structure-borne sound sensor, or as a microphone. However, a micromechanical component 50 of such a semiconductor device may also comprise an inertial sensor and/or a chemical detection sensor. It is again pointed out that the manufacture of the semiconductor devices explained above does not require expensive and vulnerable gluing of the respective micromechanical component 50 into the associated injection-molded body 52. The occurrence of acoustic leakage paths is (nearly) impossible due to the good design concept of the respective semiconductor device. In addition, each of the semiconductor devices can use its recess 56 as a relatively large reference volume. An increase in the recess 56 used as a reference volume hardly contributes to the cost increase in the manufacture of the respective semiconductor device. As can also be seen, the application-specific circuit device 62 and the micromechanical device can be formed independently of the size of the recess 56 used as a reference volume.

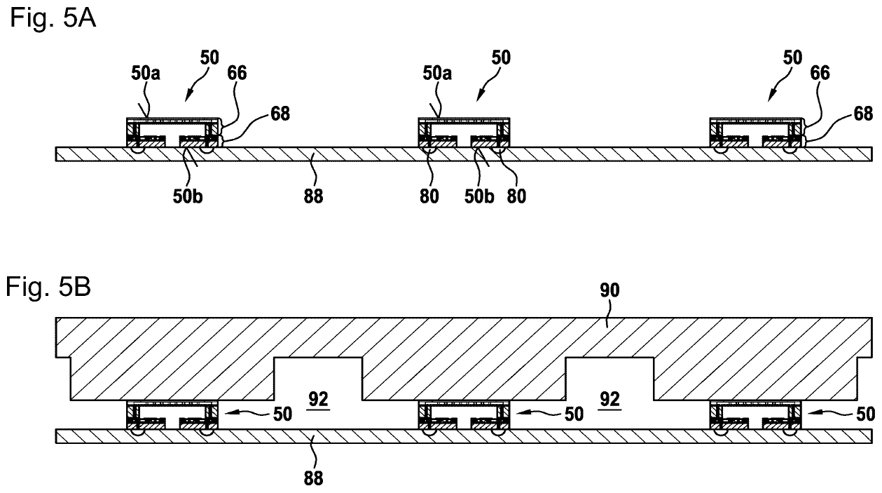

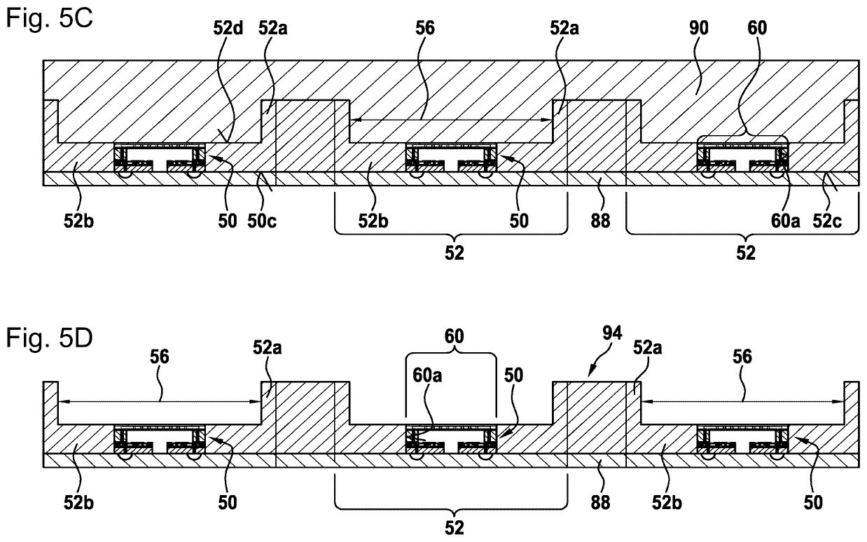

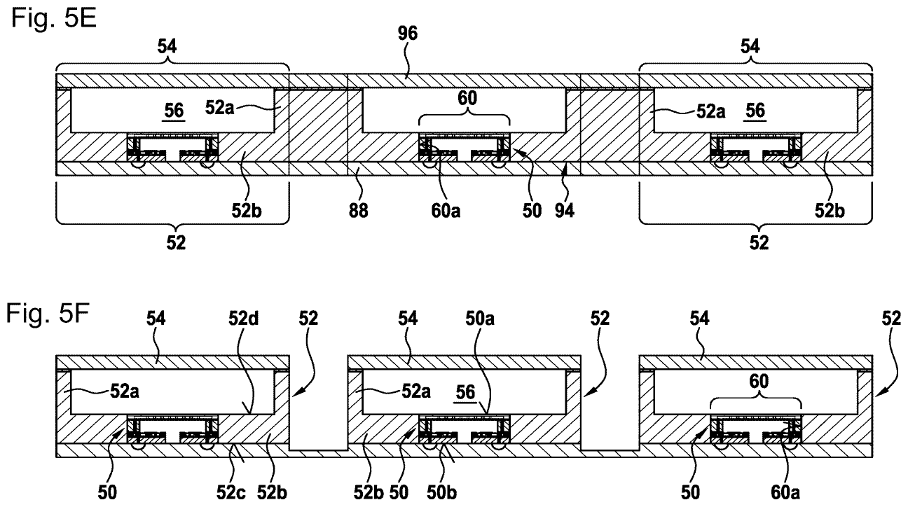

FIGS. 5A to 5F show schematic illustrations of intermediate products to explain an embodiment of the production method for a semiconductor device.

By means of the production method described below, in particular the embodiments of semiconductor devices explained above can be produced. However, it should be noted that feasibility of the production method is not limited to such a semiconductor device.

In the production method described here, one injection-molded body 52 is formed for each of at least one micromechanical component 50. As can be seen from FIG. 5A, the production method can also be carried out at wafer level in order to form one injection-molded body 52 for each of a plurality of micromechanical components 50. By carrying out all manufacturing steps of the production method described below for the plurality of micromechanical components 50 simultaneously in parallel/in an ensemble, the semiconductor devices produced in this way can be manufactured cost-effectively.

Optionally, the plurality of micromechanical components 50 can also be produced at wafer level, although this is not shown in FIG. 5A. For example, a plurality of micromechanical devices 66 of the micromechanical components 50 may be manufactured in a first wafer and a plurality of application-specific circuit devices 68 of the micromechanical components 50 may be manufactured in a second wafer. If desired, at least one solder ball 80 can also be applied to a subsequent outer component surface 50b of each micromechanical component 50.

Subsequently, the first wafer may be bonded to the second wafer such that, for each of the micromechanical components 50, the associated application-specific circuit device 68 and the associated micromechanical device are bonded together. The wafer stack obtained in this way can then be diced, wherein prior to dicing the wafer stack any openings/gaps formed on the micromechanical components 50 can be covered with a sawing film, so that no sawing dust can penetrate into the interior of the diced micromechanical components 50. A conventional sawing process can therefore also be used for dicing the micromechanical components 50.

The micromechanical components 50 separated from the wafer stack are arranged on a pad 88, as shown in FIG. 5A. The pad 88 can be a carrier 88 or a film 88, which holds the micromechanical components 50 in place during subsequent overmolding of the micromechanical components 50 and at the same time covers any openings/gaps formed on the micromechanical components 50 to prevent molding compound from penetrating. Alternatively, the micromechanical components 50 can also be soldered to a laminate as pad 88. If necessary, any openings/gaps formed on the micromechanical components 50 can also be protected with a so-called underfill, i.e. with a casting compound which, due to capillary forces, only flows on the outer component surface 50b of each micromechanical component 50 contacted by the pad 88.

In a method step shown in FIG. 5B, the pad 88 with the diced micromechanical components 50 is introduced into a molding press (not shown), wherein a punch 90 is pressed against the micromechanical components 50 on a side facing away from the pad 88. As an advantageous further development, a film (not shown) can be arranged between the punch 90 and the at least one micromechanical component 50 before overmolding the at least one micromechanical component 50 with a molding compound of its subsequent injection-molded body 52. Tolerance compensation can be achieved by using the film together with the pad 88 and the punch 90.

The punch 90 is shaped such that a free space 92 present between the pad 88 and the punch 90 pressed with or without film against the at least one micromechanical component 50 reproduces a desired shape of the at least one subsequently formed injection-molded body 52 of the at least one micromechanical component 50. As can be seen in FIG. 5C, a molding process can then be carried out to form the at least one injection-molded body 52 of the at least one micromechanical component 50, in which the at least one micromechanical component 50 is overmolded with the molding compound of the at least one subsequent injection-molded body 52 using the punch 90. As already explained above, the molding process can be carried out in particular as “film molding,” in that a tolerance compensation is achieved by means of the film between the punch 90 and the at least one micromechanical component 50, and additionally the respective surface of the at least one micromechanical component 50 is protected.

In the molding process, due to the shape of the punch 90, the at least one subsequent injection-molded body 52 is formed with a respective recess 56, which is framed by a lateral wall region 52a of the respective surrounding injection-molded body 52, while on a first side of the respective recess 56, the recess 56 is at least partially covered by a base region 52b of the subsequent injection-molded body 52. Furthermore, when forming the respective injection-molded body 52 of the at least one micromechanical component 50, the respective micromechanical component 50 is enveloped by the molding compound such that a through-opening 60 is formed at the base region 52b of the respective injection-molded body 52. Because the at least one micromechanical component 50 is pressed against the pad 88 during the molding process by means of the punch 90 with or without the film, the through-opening 60 formed in the base region 52b of its injection-molded body 52 is formed with at least one lateral wall 60a extending from the recess 56 formed in the respective injection-molded body 52 to an outer base surface 52c of the subsequent base region 52b formed in this manner facing away from the recess 56. In addition, in the molding process, the at least one micromechanical component 50 is arranged in the through-opening 60 of its subsequent injection-molded body 52 such that the at least one micromechanical component 50 mechanically contacts the at least one lateral wall 60a of the through-opening 60 formed in its injection-molded body 52.

The molding press can then be opened and the pad 88 with the at least one micromechanical component 50 arranged thereon with its respective injection-molded body 52 formed can be removed from the molding press. It may be possible to remove the film from the at least one overmolded micromechanical component 50 after overmolding the at least one micromechanical component 50 with the molding compound and removing the punch 90, which is now no longer required.

The intermediate product is illustrated in FIG. 5D. As can be seen, during injection molding to form a plurality of subsequent injection-molded bodies 52, the molded injection-molded bodies 52 may still be connected in an injection-molded body composite 94.

Subsequently, at least one lid 54 on a second side of the at least one recess 56 facing away from the first side of the at least one recess 56 is fastened directly or via at least one intermediate component 58 to the respective lateral wall region 52a of the at least one subsequent injection-molded body 52 such that the at least one lid 54 covers the recess 56 assigned to it on its second side. The at least one lid 54 can be glued directly and flatly onto the injection-molded body 52 assigned to it so as to be cost-effective. Preferably, a plurality of lids 54 are applied as a flat sheet 96 to the injection-molded body composite 94 comprising the plurality of injection molded bodies 52. The intermediate product obtained in this way is shown in FIG. 5E. In the stack of the flat sheet 96 with the plurality of lids 54 and of the injection-molded body composite 94 comprising the plurality of injection molded bodies 52, the subsequent semiconductor devices are still connected.

FIG. 5F shows the dicing of the semiconductor devices produced in the wafer composite. A conventional sawing process can be carried out for dicing, during which the micromechanical component 50 and the recess 56 of each diced semiconductor device are well protected against unwanted penetration of saw dust due to its (co-)diced lid 54 and its (co-)diced injection-molded body 52.

1-11. (canceled)

12. A semiconductor device, comprising:
a micromechanical component;
an injection-molded body with at least one recess formed on the injection- molded body, the recess being framed by a lateral wall region of the injection-molded body and being at least partially covered on a first side of the recess by a base region of the injection-molded body; and
a lid, which is fastened to the lateral wall region directly or via at least one intermediate component, on a second side of the recess facing away from the first side of the recess and covers the recess on the second side;
wherein the base region of the injection-molded body includes a through-opening, at least one lateral wall of the through-opening extending from the recess to an outer base surface of the base region facing away from the recess; and
wherein the micromechanical component is arranged in the through-opening such that the micromechanical component mechanically contacts the at least one lateral wall of the through-opening.

13. The semiconductor device according to claim 12, wherein the micromechanical component includes at least one structured or unstructured substrate including at least one semiconductor material, and wherein the micromechanical component is arranged in the through-opening such that at least one outer surface of the at least one substrate of the micromechanical component mechanically contacts the at least one lateral wall of the through-opening.

14. The semiconductor device according to claim 12, wherein the recess is covered on its first side by the base region of the injection-molded body and by the micromechanical component arranged in the through-opening.

15. The semiconductor device according to claim 12, wherein the lid is fastened to the lateral wall region in an airtight and gas-tight manner directly or via the at least one intermediate component, and the mechanical contact of the at least one lateral wall of the through-opening with the micromechanical component is airtight and gas-tight, whereby the recess is sealed in an airtight and gas-tight manner from an outer volume of the semiconductor device using the injection-molded body, the lid, and the micromechanical component.

16. The semiconductor device according to claim 15, wherein the micromechanical component arranged in the through-opening includes at least one deformable membrane, on a respective first membrane surface of which a pressure prevailing in the outer volume acts, and on a respective second membrane surface of which, facing away from the first membrane surface, a reference pressure enclosed in the recess acts.

17. The semiconductor device according to claim 12, wherein the micromechanical component arranged in the through-opening includes a spacer at its end aligned with the recess, and wherein at least one spacer side surface of the spacer mechanically contacts the at least one lateral wall of the through-opening.

18. The semiconductor device according to claim 12, wherein the micromechanical component arranged in the through-opening includes an application-specific circuit device, and wherein at least one lateral surface of the application-specific circuit device mechanically contacts the at least one lateral wall of the through-opening.

19. The semiconductor device according to claim 12, wherein the semiconductor device is a pressure sensor, or a sound sensor, or a microphone.

20. A production method for a semiconductor device, the method comp the following steps:
forming an injection-molded body for a micromechanical component with a recess formed on the injection-molded body, the recess being framed by a lateral wall region of the injection-molded body and being at least partially covered on a first side of the recess by a base region of the injection-molded body; and
fastening a lid on a second side of the recess facing away from the first side of the recess, directly or via at least one intermediate component, to the lateral wall region such that the lid covers the recess on its second side;
wherein, when forming the injection-molded body, a through-opening is formed at the base region of the injection-molded body, an at least one lateral wall of which extends from the recess to an outer base surface, facing away from the recess, of the base region, and the micromechanical component is arranged in the through-opening such that the micromechanical component makes mechanical contact with the at least one lateral wall of the through-opening.

21. The production method according to claim 20, wherein the micromechanical component is overmolded with a molding compound of the subsequent injection-molded body using a punch to form the injection-molded body.

22. The production method according to claim 21, wherein a film is arranged between the punch and the micromechanical component before the micromechanical component is overmolded with the molding compound of the subsequent injection-molded body, which is removed after the micromechanical component has been overmolded with the molding compound and the punch has been removed from the overmolded micromechanical component.
